(19) United States
(12) Patent Application Publication
(10) Pub. No.: US 2013/0309004 A1
(43) Pub. Date: Nov. 21, 2013

(54) MOUNTING DEVICE FOR CONNECTOR

(71) Applicants: HONG FU JIN PRECISION INDUSTRY (WUHAN) CO., LTD., Wuham (CN); HON HAI PRECISION INDUSTRY CO., LTD., New Taipei (TW)

(72) Inventors: XUE-JIAO GUO, Wuhan (CN); CHAO GENG, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 13/748,829

(22) Filed: Jan. 24, 2013

(30) Foreign Application Priority Data
May 18, 2012 (CN) 201210155425.0

(51) Int. Cl. H05K 7/12

(52) U.S. Cl. CPC H05K 7/12
USPC 403/280

(57) ABSTRACT

A mounting device for securing a connector includes a mounting plate and a mounting member. The mounting plate defines an installation slot and a receiving hole. The mounting member includes a protrusion and two legs. Each of the two legs is elastically deformable. The mounting member is slidably received in the installation slot, and the protrusion is engaged in the receiving hole, to prevent the mounting member from moving along a first direction, which is substantially parallel to the mounting plate. The two legs are located on two opposite sides of the mounting plate, to prevent the mounting member from moving along a second direction, which is substantially perpendicular to the mounting plate. The two legs are configured for securing an installation piece of the connector to the mounting plate.

### BACKGROUND

1. Technical Field

The present disclosure relates to mounting devices, and more particularly to a mounting device for a connector.

2. Description of Related Art

A number of connectors, such as serial connectors and parallel connectors, are used in a computer for connecting a peripheral device. Generally, each of the serial connectors and parallel connectors is secured to an installation piece, and the installation piece is engaged in an inserting slot, which is used for securing an expansion card with screws. However, securing and removing the screws are time-consuming and inconvenient, and the serial connectors and parallel connectors occupy much installation space of the expansion card.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a mounting device and a connector.

FIG. 2 is an isometric view of a mounting member of FIG. 1.

FIG. 3 is a cross-sectional view of the mounting member of FIG. 2, taken along a line III-III.

FIG. 4 is an assembled, isometric view of the mounting device and the connector of FIG. 1.

FIG. 5 is an enlarged view of a circled portion V of FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

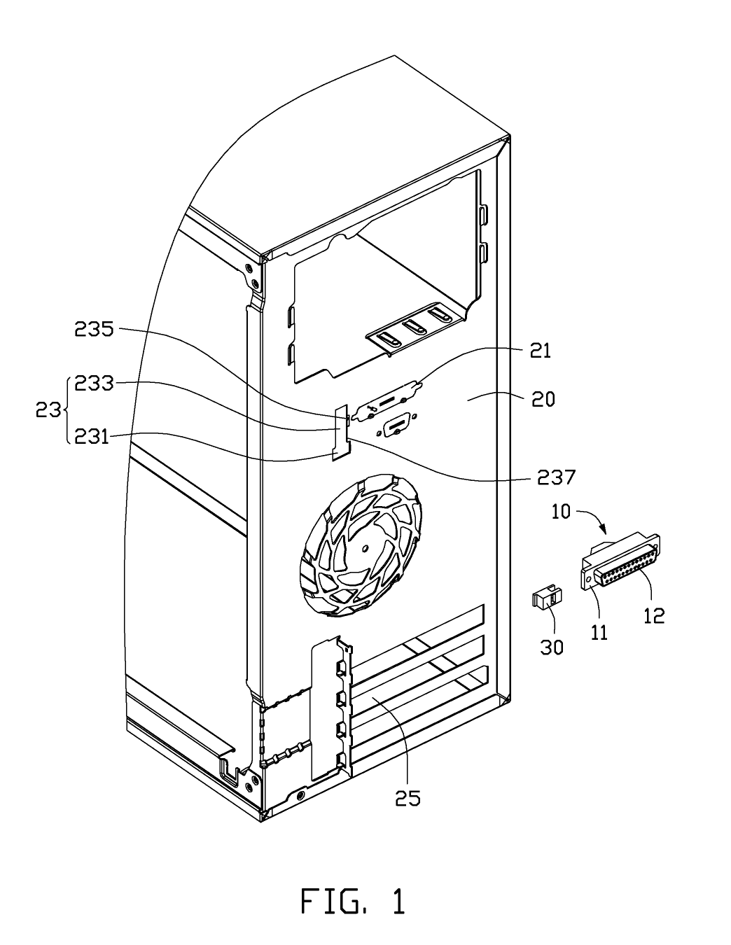

FIG. 1 illustrates one embodiment of a mounting device for securing a connector 10. The mounting device includes a mounting plate 20 and a mounting member 30. In one embodiment, the mounting plate 20 is a rear plate of an electronic device chassis.

The connector 10 includes an installation piece 11 and an inserting portion 12 located on the installation piece 11. In one embodiment, the connector 10 is a power connector or a cable connector.

The mounting plate 20 defines an opening 21, an installation slot 23, and a plurality of inserting slots 25. The installation slot 23 is located on a side of the opening 21 and includes an inserting end 231 and an installation end 233. A width of the inserting end 231 is greater than a width of the installation end 233, so as to form two positioning pieces 237 on two opposite ends of the installation end 233. The mounting plate 20 further defines a receiving hole 235. The receiving hole 235 extends from a side edge of the installation slot 233 towards the opening 21 and communicates with the installation end 233. Each of the inserting slots 25 is used for securing an expansion card (not shown). In one embodiment, the receiving hole 235 is semicircular.

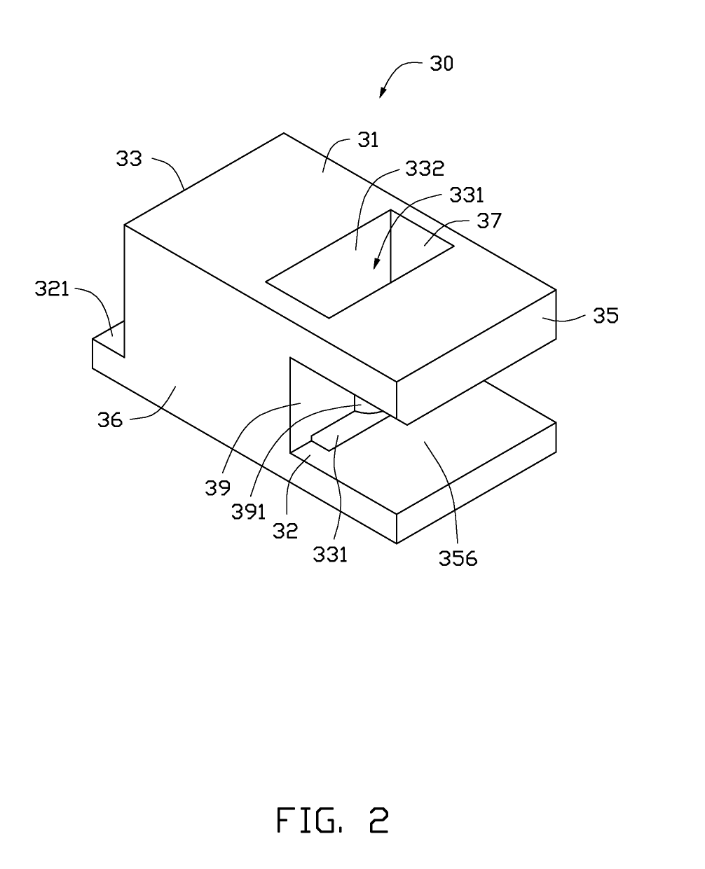

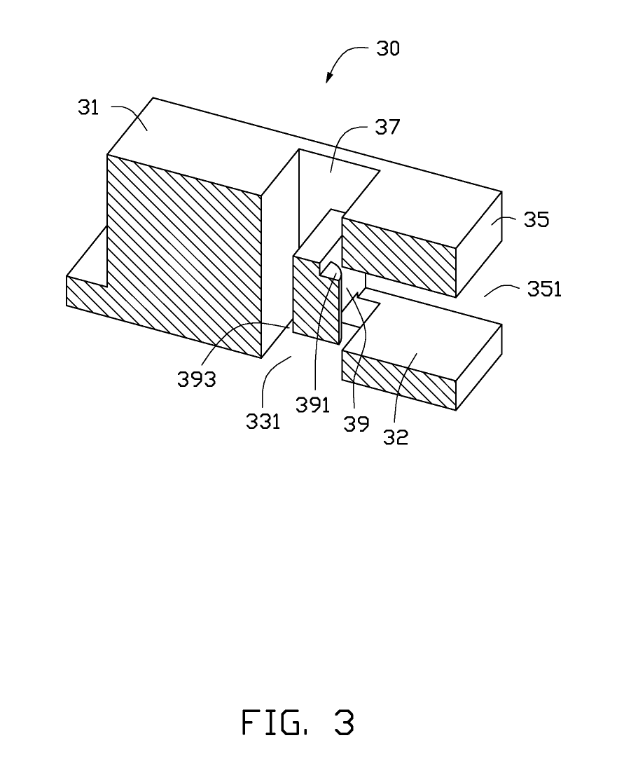

FIG. 2 and FIG. 3 show the mounting member 30 including a top wall 31, a bottom wall 32, a first sidewall 33, a second sidewall 35, a front wall 36, and a rear wall 37. In one embodiment, the top wall 31 is substantially parallel to the bottom wall 32, the first sidewall 33 is substantially parallel to the second sidewall 35, the front wall 36 is substantially parallel to the rear wall 37, the top wall 31 and the bottom wall 32 are substantially perpendicular to the first sidewall 33, the second sidewall 35, the front wall 36, and the rear wall 37, and the first sidewall 33 and the second sidewall 35 are substantially perpendicular to the front wall 36 and the rear wall 37.

A limiting piece 321 extends outwards from the bottom wall 32. The limiting piece 321 extends out of the first sidewall 33. The mounting member 30 defines a first slot 331. The first slot 331 extends from the top wall 31 to the bottom wall 32. A connector plane 332 of the first slot 331 is substantially perpendicular to the top wall 31. The mounting member 30 further defines a second slot 351 and includes two legs 356 on two opposite sides of the second slot 351. The second slot 351 communicates with the first slot 331 and extends through the front wall 36 and the rear wall 37. An extending direction of the first slot 331 is substantially perpendicular to the second slot 351. A mounting piece 39 is connected between the front wall 36 and the rear wall 37 and located in the first slot 331. In one embodiment, the mounting piece 39 is substantially parallel to the connecting plane 332. A distance between the first sidewall 33 and the mounting piece 39 is substantially equal to a distance between the two positioning pieces 237. A receiving space 393 is defined between the mounting piece 39 and the connecting plane 332 for receiving the mounting piece 39 when the mounting piece 39 is elastically deformed towards the connecting plane 332. A protrusion 391 extends from the mounting piece 39. The protrusion 391 can be received in the receiving hole 235. In one embodiment, the protrusion 391 has a semicircular outer surface.

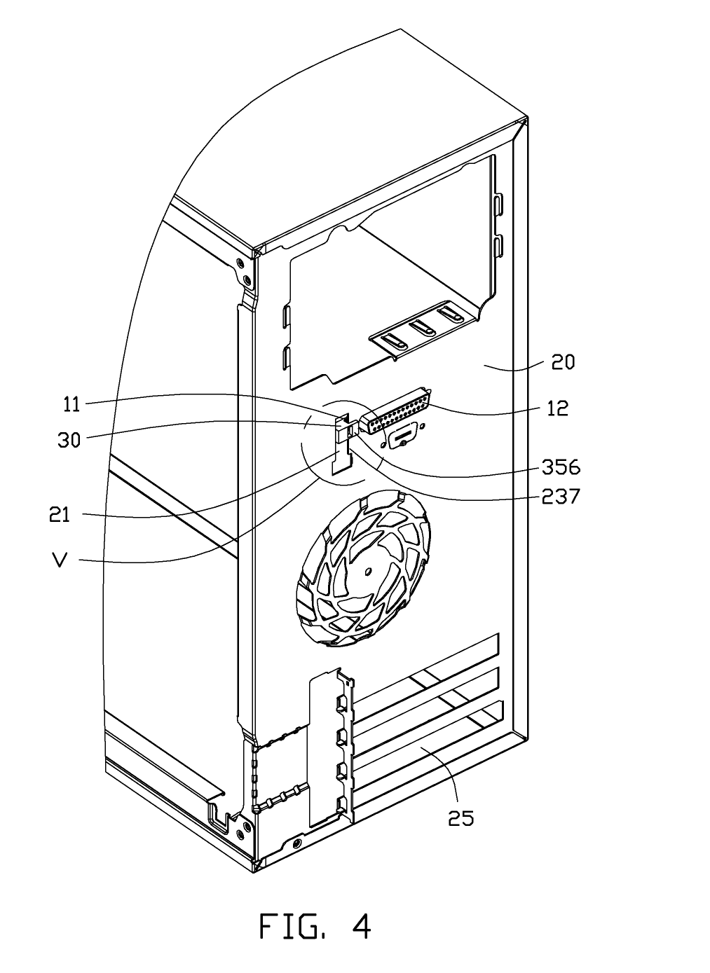

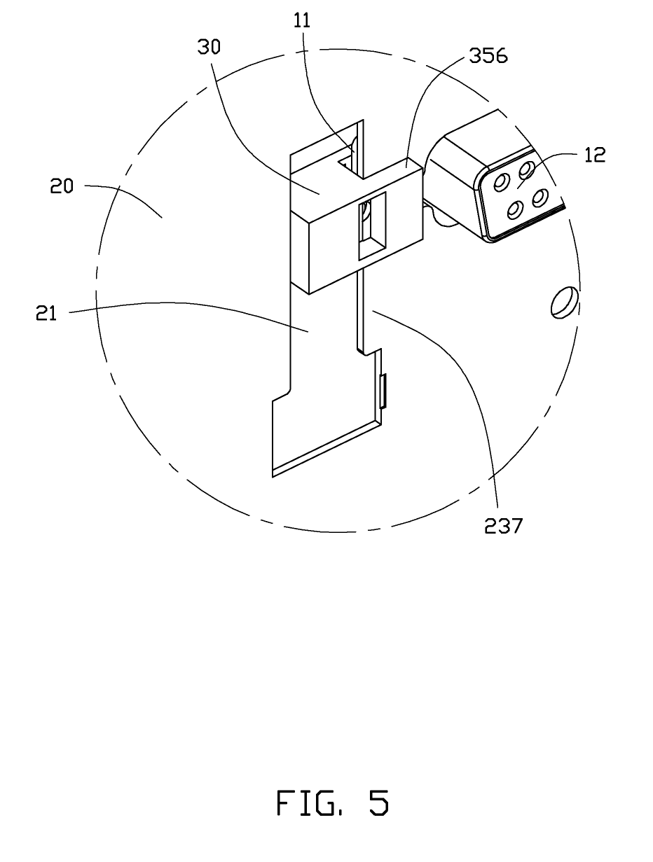

FIG. 4 and FIG. 5 show that, in assembly, the inserting portion 12 extends out of the mounting plate 20 from an inner surface of the mounting plate 20 through the opening 21. The installation piece 11 abuts the inner surface of the mounting plate 20. The mounting member 30 is inserted into the inserting end 231 of the installation slot 23, and the two legs 356 are located on two opposite sides of the mounting plate 20, and the limiting piece 321 abuts the inner surface of the mounting plate 20. The mounting member 30 is slid towards the installation end 233. Each of the two positioning pieces 237 presses the protrusion 391 and elastically deforms the mounting piece 39 towards the connecting plane 332, until the two legs 356 are blocked by the installation piece 11. The mounting member 30 is further slid and elastically deforms the two legs 356, until the protrusion 391 is aligned with the receiving hole 235. The mounting piece 39 rebounds to engage the protrusion 391 in the receiving hole 235. The two legs 356 exert elastically force to engage the installation piece 11 to each of the two positioning pieces 237. Thus, the mounting member 30 is secured to the mounting plate 20 and secures the connector 10 to the mounting plate 20. A part of the mounting member 30 is received in the installation slot 23, and the protrusion 391 is received in the receiving hole 235, to prevent the mounting member 30 from moving along a direction substantially parallel to the mounting plate 20. The two legs 356 are located on two opposite sides of the mounting plate 20, to prevent the mounting plate 20 from moving along a direction substantially perpendicular to the mounting plate 20.

In disassembly, the mounting member 30 is slid towards the inserting end 231 to elastically deform the mounting piece 39 towards the connecting plane 332, and the protrusion 391 can be disengaged from the receiving hole 235. Thus, the mounting member 30 can be removed from the installation slot 23. The connector 10 is disengaged from the two legs 356, thus the connector 10 can be removed from the mounting plate 20.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A mounting device for securing a connector comprising:
a mounting plate defining an installation slot and a receiving hole; and
a mounting member comprising a protrusion and two legs; and each of the two legs being elastically deformable;
wherein the mounting member is slidably received in the installation slot, and the protrusion is engaged in the receiving hole to prevent the mounting member from moving along a first direction, the first direction being substantially parallel to the mounting plate; and the two legs are located on two opposite sides of the mounting plate to prevent the mounting member from moving along a second direction, the second direction being substantially perpendicular to the mounting plate; and the two legs are configured for securing an installation piece of the connector to the mounting plate.

2. The mounting device of claim 1, wherein the installation slot comprises an inserting end and an installation end, and a width of the inserting end is greater than a width of the installation end, two positioning pieces are formed on two opposite sides of the installation end; and the mounting member is engaged in the installation end through the inserting end and received between the two positioning pieces.

3. The mounting device of claim 2, wherein the receiving hole is defined in one of the two positioning pieces, and the receiving hole communicates with the installation end.

4. The mounting device of claim 2, wherein the mounting member comprises a top wall, a bottom wall, a front wall, a rear wall, a first sidewall, and a second sidewall; the top wall is substantially parallel to the bottom wall, the first sidewall is substantially parallel to the second sidewall, the front wall is substantially parallel to the rear wall, the top wall and the bottom wall are substantially perpendicular to the first sidewall, the second sidewall, the front wall, and the rear wall, and the first sidewall and the second sidewall are substantially perpendicular to the front wall and the rear wall; the mounting member defines a first slot and a second slot; the first slot extends from the top wall to the bottom wall, and the second slot extends from the front wall to the rear wall; and the second slot is located between the two legs.

5. The mounting device of claim 4, wherein an extending direction of the first slot is substantially perpendicular to an extending direction of the second slot.

6. The mounting device of claim 4, wherein first slot comprises a connecting plane; the two legs are connected to the connecting plane; the mounting member further comprises a mounting piece located in the first slot and is connected to the front wall and the rear wall; and the protrusion protrudes from the mounting piece.

7. The mounting device of claim 6, wherein the first sidewall and the connecting plane are located in the inserting end and abut the two positioning pieces.

8. The mounting device of claim 6, wherein a distance between the first sidewall and the connecting plane is substantially equal to a distance between the two positioning pieces.

9. The mounting device of claim 6, wherein a receiving space is defined between the mounting piece and the connecting plane; and the receiving space receives the mounting piece when the mounting piece is elastically deformed.

10. The mounting device of claim 6, wherein the mounting piece is substantially parallel to the connecting plane and the first sidewall.

11. A mounting device for securing a connector comprising:
a mounting plate defining an installation slot and a receiving hole; and
a mounting member defining a first slot and a second slot and comprising a mounting piece, a protrusion protruding from the mounting piece, and two legs; the mounting piece is located in the first slot; the two legs are located on two opposite sides of the second slot; and the mounting piece and each of the two legs being elastically deformable;
wherein the mounting member is slidably received in the installation slot, and the protrusion is engaged in the receiving hole to prevent the mounting member from moving along a first direction, the first direction being substantially parallel to the mounting plate; and the two legs are located on two opposite sides of the mounting plate to prevent the mounting member from moving along a second direction, the second direction being substantially perpendicular to the mounting plate; and the two legs are configured for securing an installation piece of the connector to the mounting plate.

12. The mounting device of claim 11, wherein the installation slot comprises an inserting end and an installation end, and a width of the inserting end is greater than a width of the installation end, so as to form two positioning pieces on two opposite sides of the installation end; and the mounting member is engaged in the installation end through the inserting end and received between the two positioning pieces.

13. The mounting device of claim 12, wherein the receiving hole is defined in one of the two positioning pieces, and the receiving hole communicates with the installation end.

14. The mounting device of claim 12, wherein the mounting member comprises a top wall, a bottom wall, a front wall, a rear wall, a first sidewall, and a second sidewall; the top wall is substantially parallel to the bottom wall, the first sidewall is substantially parallel to the second sidewall, the front wall is substantially parallel to the rear wall, the top wall and the bottom wall are substantially perpendicular to the first sidewall, the second sidewall, the front wall, and the rear wall, and the first sidewall and the second sidewall are substantially perpendicular to the front wall and the rear wall; the first slot extends from the top wall to the bottom wall, and the second slot extends from the front wall to the rear wall.

15. The mounting device of claim 14, wherein an extending direction of the first slot is substantially perpendicular to an extending direction of the second slot.

16. The mounting device of claim 14, wherein first slot comprises a connecting plane; the two legs are connected to the connecting plane; the mounting piece is connected to the front wall and the rear wall.

17. The mounting device of claim 16, wherein the first sidewall and the connecting plane are located in the inserting end and abut the two positioning pieces.

18. The mounting device of claim 16, wherein a distance between the first sidewall and the connecting plane is substantially equal to a distance between the two positioning pieces.

19. The mounting device of claim 16, wherein a receiving space is defined between the mounting piece and the connecting plane; and the receiving space received the mounting piece when the mounting piece is elastically deformed.

20. The mounting device of claim 16, wherein the mounting piece is substantially parallel to the connecting plane and the first sidewall.
